(19) United States
(12) Patent Application Publication
(10) Pub. No.: US 2026/0038625 A1
(43) Pub. Date: Feb. 5, 2026

(54) SEMICONDUCTOR MEMORY DEVICE AND CONTROL METHOD THEREOF

(71) Applicant: Winbond Electronics Corp., Taichung City (TW)

(72) Inventor: Taihei SHIDO, Yokohama (JP)

(73) Assignee: Winbond Electronics Corp., Taichung City (TW)

(21) Appl. No.: 19/077,480

(22) Filed: Mar. 12, 2025

(30) Foreign Application Priority Data
Aug. 2, 2024 (JP) 2024-127942

(51) Int. Cl. G11C 29/56

(52) U.S. Cl. CPC G11C 29/56012; G11C 29/56016; G11C 2029/5602

(57) ABSTRACT

A semiconductor memory device and its control method that can reduce the increase in manufacturing costs of external devices are provided. The semiconductor memory device including a calibration circuit that performs ZQ calibration operations; and a resistor part, used as a reference resistor during ZQ calibration operations. Additionally, the control method for the semiconductor memory device, which includes the resistor part used as a reference resistor in ZQ calibration operations, which include steps of using the resistor part by the calibration circuit of the semiconductor memory device to perform the ZQ calibration operation.

### CROSS REFERENCE TO RELATED APPLICATIONS

This Application claims priority of Japanese Patent Application No. 2024-127942, filed on August 2,2024, the entirety of which is incorporated by reference herein.

### BACKGROUND OF THE INVENTION

### Field of the Invention

The present invention relates to semiconductor memory devices and control methods thereof.

### Description of the Related Art

In order to integrate the impedance of the transmission path with the output impedance of the output circuit in conventional semiconductor memory devices, it is well-known practice to connect resistors disposed outside the semiconductor memory (external resistors) device to the ZQ terminal of the semiconductor memory device, and then to perform a ZQ calibration (for example, Japanese Unexamined Patent Publication No. 2007-123987).

### BRIEF SUMMARY OF THE INVENTION

In traditional technology, the cost of manufacturing an external device (an external system) that contains external resistors may increase due to the need to connect external resistors to the ZQ terminal. In addition, if the semiconductor memory device has multiple silicon chips (memory die), such as Dual Die Package (DDP), the manufacturing cost of an external device (external system) that includes external resistors may be further increase due to different external resistors connected to multiple silicon dies.

In view of the above problems, a semiconductor memory device capable of mitigating the increase in manufacturing cost of an external device and a control method thereof is provided in the present invention.

To solve the above problems, the present invention provides a semiconductor memory device comprising a calibration circuit, performing a ZQ calibration operation, and a resistor part for use as a reference resistor in a ZQ calibration operation.

According to this invention, the need for setting an external resistor for ZQ calibration on an external device can be eliminated because the ZQ calibration operation can be performed using the resistor part disposed on the semiconductor memory device. As a result, the increase in manufacturing cost of external devices due to setting external resistors can be mitigated.

In addition, a control method of a semiconductor memory device includes a resistor part for use as a reference resistor in a ZQ calibration operation. The control method of a semiconductor memory device includes a calibration circuit using a resistor part to perform a ZQ calibration operation.

Based on the semiconductor memory device and its control method, the increase in manufacturing costs of external devices can be mitigated.

### BRIEF DESCRIPTION OF THE DRAWINGS

FIG. 1 shows a schematic structure of a semiconductor memory device according to an embodiment of the present invention;

FIG. 2 is a schematic diagram of the structural example of the resistance unit;

FIG. 3A is a schematic diagram of the structural example of adjusting the resistance value of a resistance unit;

FIG. 3B is an example of a timing diagram of the voltage value corresponding to the resistance value of the resistance unit; and

FIG. 4 is an example of a timing diagram of the output voltage of the calibration circuit in the calibration operation.

### DETAILED DESCRIPTION OF THE INVENTION

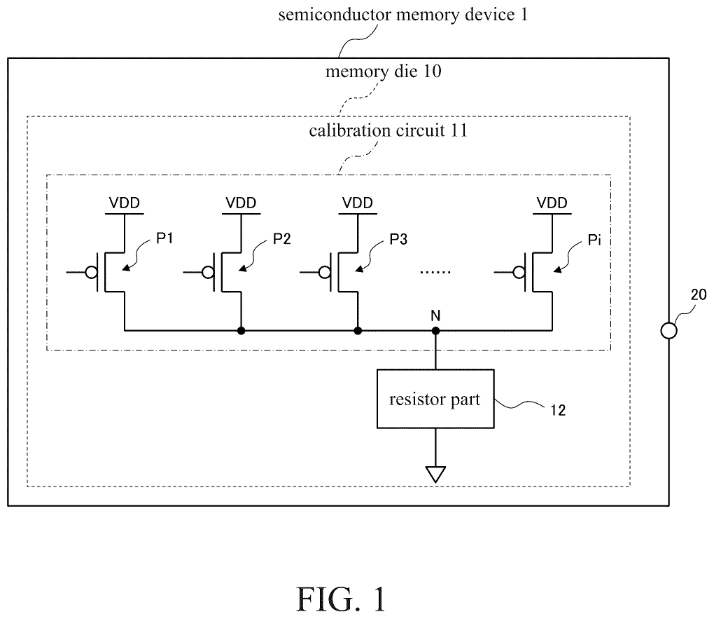

Referring to FIG. 1, semiconductor memory device 1 is a dynamic random access memory (DRAM) such as Double Data-Rate 4 Synchronous Random Access Memory, DDR4 SDRAM, etc., and includes more than one memory die (chip) 10. In addition, in this embodiment, semiconductor memory device 1 has a ZQ terminal 20 on more than one memory die 10. In addition, although FIG. 1 shows that a semiconductor memory device 1 contains a memory die 10, a semiconductor memory device 1 can include multiple memory dice 10. In addition, to simplify the illustration, other known components of semiconductor memory device 1 (e.g., power supply circuit, command decoder, address decoder, clock generator, etc.) are not shown here.

In this embodiment, the memory die 10 includes a calibration circuit 11 and a resistor part 12.

The calibration circuit 11 includes a plurality of P-channel metal-oxide semiconductor field effect transistors (MOSFETs) P1-Pi (i is an integer of 2 or more) and configured to perform a ZQ calibration operation. The source terminal of each P-channel MOSFET P1-Pi is connected to the operating voltage VDD, and the drain terminal of each P-channel MOSFET P1-Pi is connected to resistor part 12 through node N. In addition, the gate terminals of each P-channel MOSFET P1-Pi receives an input control signal used to regulate the ON/OFF switching of each P-channel MOSFET P1-Pi.

Besides, in this embodiment, although the calibration circuit 11 includes multiple P-channel MOSFETs P1-PIs as an example, the calibration circuit 11 may include multiple N-channel MOSFETs instead of multiple P-channel MOSFETs P1-Pi, and may include multiple other transistors, or may include multiple switching circuits. In addition, the calibration operation in the calibration circuit 11 will be explained later.

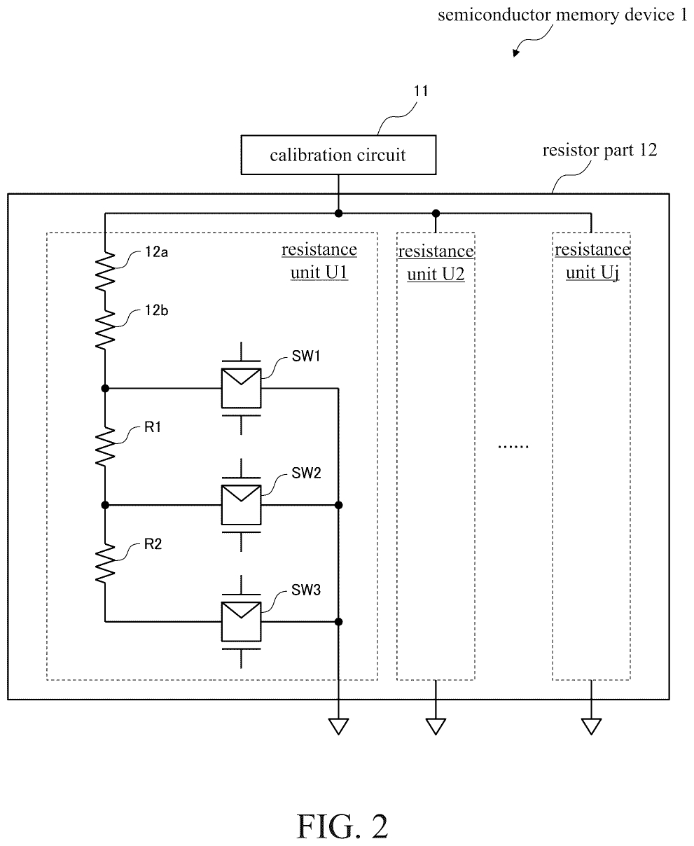

The resistor part 12 is configured for use as a reference resistor in ZQ calibration operation. Besides, in this embodiment, resistor part 12 includes resistance units U1˜Uj (j is an integer above 2) parallel to the calibration circuit 11 as shown in FIG. 2. As a result, multiple resistance units U1˜Uj can be used to form the reference resistor in ZQ calibration operation.

In this embodiment, each of resistance units U1˜Uj contains multiple (in the example shown in FIG. 2, there are 4) series-connected resistors 12a, 12b, the first resistor R1, the second resistor R2, and multiple (in the example shown in FIG. 2, there are 3) switch parts (switch part SW1, switch part SW2, switch part SW3). In addition, the structure of each of the multiple resistance units U1˜Uj is as follows: one end of the N^{th} switch part SWN (where N is an integer of 1 or more) is connected to one end of the N^{th} resistor RN, and one end of the (N+1)^{th} switch part SW(N+1) is connected to the other end of the Nth resistor RN. The other end of the N^{th} switch part SWN and the other end of the (N+1)^{th} switch part SW(N+1) are connected to each other. Specifically, in the example shown in FIG. 2, one end of the switch part SW1 is connected to one end of the resistor R1, one end of the switch part SW2 is connected to the other end of the resistor R1, the other end of the switch part SW1 and the other end of the switch part SW2 are connected to each other. In addition, one end of the switch part SW2 is connected to one end of the second resistor R2, one end of the switch SW3 is connected to the other end of the second resistor R2, the other end of the switch part SW2 and the other end of the third switch SW3 are connected to each other.

Besides, in this embodiment, although the case of multiple resistance units U1˜Uj each has three switch parts (switch part SW1, switch part SW2 and switch part SW3) as an example, the number of switch parts provided by multiple resistance units U1˜Uj may be 2 or less, or more than 4. In addition, the number of switch parts provided by multiple resistance units U1˜Uj may be the same or different between multiple resistance units U1˜Uj.

Furthermore, in this embodiment, although the case where each of the multiple resistance units U1˜Uj is equipped with 4 resistors 12a, 12b, the first resistor R1, and the second resistor R2 is described as an example, the number of resistors each equipped within can be less than 3, or more than 5. In addition, the number of resistors equipped by multiple resistance units U1˜Uj can be the same or different from U1˜Uj.

Each of the multiple resistance units U1˜Uj is configured to: when any of the multiple switch parts (switch part SW1, switch part SW2, or switch part SW3) is in a conducting state, it has a resistance value corresponding to the conducting switch part. Specifically, each of the multiple resistance units U1˜Uj is controlled in such a way that only one of the multiple switch parts (switch part SW1, switch part SW2, and switch part SW3) is in the conducting state. For example, when the switch part SW1 of the resistance unit U1 is in the conducting state, the switch part SW2 and the switch part SW3 are turned off, the resistance value of the resistance unit U1 is represented by the sum of the respective resistance values of resistor 12a and resistor 12b. In addition, when the switch part SW2 of the resistance unit U1 is in the conducting state, the switch part SW1 and the switch part SW3 are turned off, the resistance value of the resistance unit U1 is expressed by the sum of the respective resistance values of resistor 12a, resistor 12b and first resistor R1. Furthermore, when the switch part SW3 of the resistance unit U1 is in the conducting state, the switch part SW1 and the switch part SW2 are turned off, the resistance value of the resistance unit U1 is expressed by the sum of the respective resistance values of resistor 12a, resistor 12b, the first resistor R1 and the second resistor R2. In this way, each of the multiple resistance units U1˜Uj may have different resistance values depending on the switch part in the conducting state.

In addition, in this embodiment, each of the multiple switch parts (switch part SW1, switch part SW2, and switch part SW3) contain a transfer transistor. Thus, by changing any of the P-channel MOSFETs and N-channel MOSFETs that make up the transfer transistor into the conducting state, the transfer transistor can be easily turned into the conducting state. In addition, although the multiple switch parts (switch part SW1, switch part SW2, and switch part SW3) are configured as an example to contain transfer transistors, it is also possible to configure at least one of the multiple switch parts (switch part SW1, switch part SW2, and switch part SW3) to contain other switching circuits other than the transfer transistors (e.g., P-channel MOSFETs, N-channel MOSFETs, etc.).

In addition, each of multiple resistance units U1˜Uj may include the same resistance value. Thus, a resistance unit U1˜Uj including the same resistance value can be used to form a reference resistor in ZQ calibration operation easily. For example, if resistor part 12 has a resistance value of 24052 and the number of resistance units is 10, the resistance value of each resistance unit can be set to 240062.

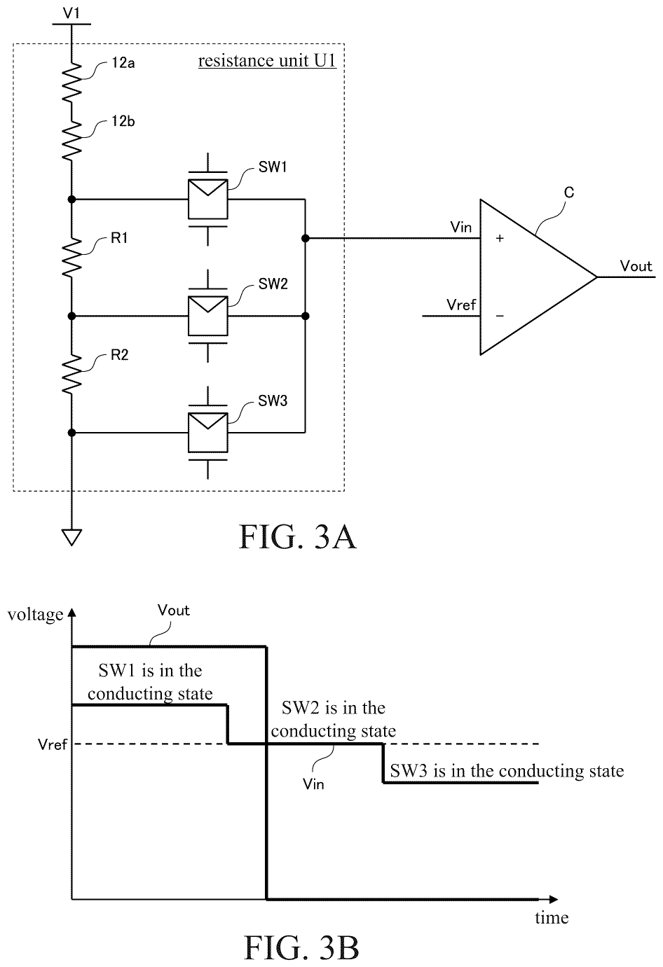

Here, refer to FIG. 3A and FIG. 3B for an example of adjusting the resistance values of multiple resistance units U1˜Uj. As shown in FIG. 3A, a specific voltage V1 is applied to the resistor unit U1, and the other end of each of switch parts (switch part SW1, switch part SW2, switch part SW3) is connected to the input terminal of one end (+side) of the comparator C. In addition, the input terminal on the other end (−side) of comparator C is input to a specific reference voltage Vref. Furthermore, comparator C compares the voltage Vin of the input terminal input on one end (+side) to the reference voltage Vref of the input terminal on the other end (−side) and outputs the comparison result as the output voltage Vout. In this embodiment, when the output voltage of the resistance unit U1 (i.e., voltage Vin) is equal to the reference voltage Vref, the resistance unit U1 has the desired resistance value and adjust the resistance value of the resistance unit U1.

As shown in FIG. 3B, in the resistance unit U1, the switch part SW1 is set as the conducting state first, and then the switch part SW2 is set to the conducting state, and then the switch part SW3 is set to the conducting state. Then, in the multiple switch parts (switch part SW1, switch part SW2, switch part SW3), which one of the switch parts has the same voltage Vin as the reference voltage Vref when it is set to the conducting state is determined (in the example shown in FIG. 3B, the switch part SW2), and the discriminated switch part is set to the conducting state, thus adjusting the resistance value of the resistance unit U1. In addition, the resistance value can also be adjusted for other resistor units U2˜Uj.

In addition, according to the process and temperature characteristics, the resistance values of resistors 12a, 12b, the first resistor R1, and the second resistor R2 equipped in the multiple resistance units U1 to Uj may be different from those in the multiple resistance units U1 to Uj, so when set to the conducting state, the switch part that equalizes the input voltage Vin and the reference voltage Vref can be different among the multiple resistance units U1˜Uj. Besides, in the example shown in FIG. 3B, the switch part SW1 is set to the conducting state, then the switch part SW2 is set to the conducting state, and then the switch part SW3 is set to the conducting state, it is also possible to arbitrarily determine the sequence of the switch part set to the conducting state. (e.g., the switch part SW3 can be set as the conducting state, then the switch part SW2 as the conducting state, and then the switch part SW1 as the conducting state).

Back to FIG. 1, ZQ terminal 20 is a terminal that can be connected to an external resistor for ZQ calibration operation. In addition, since the resistor part 12 used as the reference resistor in the ZQ calibration operation is set in the semiconductor memory device 1, the ZQ terminal 20 does not have to include the same structure as conventional technology (i.e., a structure that can be connected to the calibration circuit 11 and an external resistor separately). In this embodiment, ZQ terminal 20 is set not connected to calibration circuit 11 and resistor part 12.

Besides, in conventional semiconductor memory devices, in addition to ZQ terminal 20, there are terminals for data input and output (e.g., DQ terminals). Here, the data input/output terminals (pad) need to be formed into a size that can be contacted by the probe pin (or probe needle) during wafer testing with the probe card. However, when the size of the data input/output terminals (pad size) becomes larger, charge and discharge current on the data input/output terminals increases, so there may be concerns about increasing power consumption of semiconductor memory devices. In addition, apart from the data output terminals used for normal operation in semiconductor memory devices, it is also possible to consider incorporating dedicated data output terminals for wafer testing within semiconductor memory devices. However, in such case, there may be concerns about potential size increase in the semiconductor memory devices (memory dies) as new data output terminal specifically for wafer testing need to bo incorporated within the semiconductor memory devices (memory dies).

Therefore, in this embodiment, the ZQ terminal 20 is configured for data input and output during wafer testing. As a result, the size of the terminal (DQ terminal) used for data output used by the semiconductor memory device 1 during normal operation (the size of the pad) does not need to be increased, and the increase in power consumption of the semiconductor memory device 1 can be mitigated. In addition, since there is no need to incorporate a dedicated data output terminal for wafer testing, the increase in the size of semiconductor memory device 1 (memory die 10) can be mitigated.

In this embodiment, ZQ terminal 20 can be connected between data input/output circuits, such as data signals (DQ) and data strobe signals (DQS,/DQS) and external devices (figures omitted). In addition, the ZQ terminal 20 can be formed to a size that can be in contact with the probe pin of the probe card during the wafer testing. Thus, the data input and output circuit of the semiconductor memory device 1 can transmit and receive data between the ZQ terminal 20 and the probe card during wafer testing, and can transmit and receive data between the terminal for data output (DQ terminal) and the external device during normal operation. In addition, the switching of terminals for data transmission and reception can be carried out, for example, by switching circuits.

In addition, although FIG. 1 shows a case in which a ZQ terminal 20 is set for a memory die 10, if the semiconductor memory device 1 includes a plurality of memory dice 10, a ZQ terminal 20 can be set for each of memory dice 10, or a shared ZQ terminal 20 can be set in a plurality of memory dice 10.

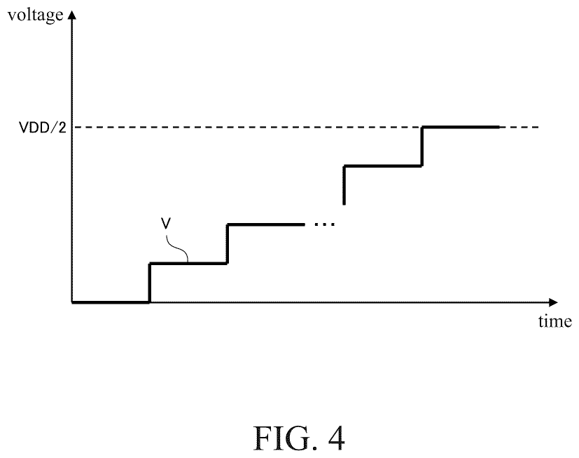

Referring to FIG. 4, the calibration operation performed in the calibration circuit 11 of the semiconductor memory device 1 of the present embodiment is illustrated. In present embodiment, the calibration circuit 11 is calibrated using a resistor part 12. In addition, here is the case where it is assumed that the voltage V of node N in FIG. 1 is equal to a specific voltage (e.g., VDD/2), the impedances in the resistor part 12 are integrated to perform the calibration operation in calibration circuit 11.

At the beginning of the calibration operation, multiple P-channel MOSFETs P1-PIs are turned off. First, the P-channel MOSFET P1 is set to conducting state, the voltage V of node N will rise. Next, while the P-channel MOSFET P1 is in conducting state, the P-channel MOSFET P2 is set to conducting state, the voltage V of node N will rise incrementally. Furthermore, when P-channel MOSFET P1 and P2 are in conducting state, the P-channel MOSFET P3 is set to conducting state, the voltage V of node N will rise further. As a result, the calibration operation can be performed by sequentially setting multiple P-channel MOSFETs P1˜Pi to the conducting state until the voltage V of the node N is equal to a specific voltage (e.g., VDD/2). In addition, although the voltage V of node N rises to a specific voltage (e.g., VDD/2) is shown in FIG. 4, the calibration operation can be performed if the voltage V of node N is decreased to a specific voltage (e.g., VDD/2) (i.e., multiple P-channel MOSFETs P1˜Pi are each set to the conducting state at the beginning of the calibration operation, and then to the off state until the voltage V of node N is equal to a specific voltage (e.g., VDD/2).

In addition, the node N of the calibration circuit 11 can be connected to, for example, a terminal (pad) for data signals (DQ) (figures omitted) or a terminal (pad) for data strobe signals (DQS,/DQS) (figures omitted), etc. In this way, the resistance obtained from the calibration operation (i.e., the composite resistance of at least one P-channel MOSFET set to the conducting state in multiple P-channel MOSFETs P1˜Pi) can be set as the output impedance.

As mentioned above, according to the semiconductor memory device 1 and its control method in the present embodiment, the need to set an external resistor for ZQ calibration in an external device can be eliminated because the resistor part 12 in the semiconductor memory device 1 can be used to perform ZQ calibration. In this way, it is possible to suppress the increase in the manufacturing cost of external devices due to the installation of external resistors.

The embodiments described above are documented to make the invention easier to understand, and are not intended to limit the invention. Therefore, the components disclosed in the aforementioned embodiments include all design changes and equivalents in the technical scope of the invention.

For example, although the case of a semiconductor memory device as a DRAM is illustrated as an example in the above embodiments, the invention is not limited to this. For example, a semiconductor memory device can be SRAM (Static Random Access Memory) or pSRAM (pseudo-Static Random Access Memory) or flash memory or other semiconductor memory devices.

In addition, the respective structures of the calibration circuit 11 and the resistor part 12 shown in FIG. 1 and FIG. 2 are only examples and can be appropriately changed, or a known structure or other various structures can also be adopted.

What is claimed is:

1. A semiconductor memory device, comprising:
a calibration circuit, configured to perform a ZQ calibration operation; and
a resistor part, configured to serve as a reference resistor in the ZQ calibration operation.

2. The semiconductor memory device as claimed in claim 1, further comprising:
a terminal connectable to an external resistor for the ZQ calibration operation, wherein the terminal is used for data input and output during wafer testing.

3. The semiconductor memory device as claimed in claim 2, wherein the terminal is not connected to the calibration circuit and the resistor part.

4. The semiconductor memory device as claimed in claim 1, further comprising: a plurality of memory dies, wherein the resistor part is arranged in each of the memory dies.

5. The semiconductor memory device as claimed in claim 1, wherein the resistor part includes a plurality of resistance units connected in parallel.

6. The semiconductor memory device as claimed in claim 5, wherein each of the plurality of resistance units include the same resistance value.

7. The semiconductor memory device as claimed in claim 5, wherein at least one of the resistance units includes a plurality of switch parts, and is configured to have a resistance value corresponding to the conducting switch part in a conducting state when any of the switch parts is in conducting state.

8. The semiconductor memory device as claimed in claim 7, wherein at least one of the plurality of switch parts includes a transfer transistor.

9. The semiconductor memory device as claimed in claim 7, wherein the at least one of the resistance units includes:
a plurality of resistors connected in series;
an N^{th} switch part, having one end connected to one end of an N^{th} resistor in the resistors, where N is an integer of 1 or more; and
an (N+1)^{th} switch part, having one end connected to the other end of the N^{th} resistor;
wherein the other end of the N^{th} switch part is connected to the other end of the (N+1)^{th} switch part.

10. The semiconductor memory device as claimed in claim 1, wherein the semiconductor memory device is a dynamic random access memory.

11. A method of controlling a semiconductor memory device, wherein the semiconductor memory device comprises a resistor part configured to serve as a reference resistor in a ZQ calibration operation, and the method of controlling the semiconductor memory device comprises steps of using the resistor part by a calibration circuit of the semiconductor memory device to perform the ZQ calibration operation.
